(19) United States
(12) Patent Application Publication
(10) Pub. No.: US 2026/0354066 A1
(43) Pub. Date: Nov. 5, 2026

(54) ETCHING METHOD AND PLASMA PROCESSING SYSTEM

(71) Applicant: Tokyo Electron Limited, Tokyo (JP)

(72) Inventors: Takayuki SUZUKI, Miyagi (JP); Ryu NAGAI, Miyagi (JP); Koki CHINO, Miyagi (JP); Yuichi FUJISAWA, Miyagi (JP); Sho SAITOH, Miyagi (JP)

(73) Assignee: Tokyo Electron Limited, Tokyo (JP)

(21) Appl. No.: 19/719,201

(22) Filed: Jun. 25, 2026

Related U.S. Application Data
(63) Continuation of application No. PCT/JP2024/045899, filed on Dec. 25, 2024.

(30) Foreign Application Priority Data
Jan. 9, 2024 (JP) 2024-001101

(51) Int. Cl. H10P 50/28; H01J 37/32; H10P 50/00

(52) U.S. Cl. CPC H10P 50/283; H01J 37/32724; H01J 37/32816; H10P 50/73; H01J 2237/3341

(57) ABSTRACT

An etching method includes (a) providing a substrate into a chamber. The substrate includes a first film and a second film defining an opening on the first film. The first film is a film stack including a first layer containing silicon and oxygen and a second layer containing silicon and nitrogen. The second film includes a metal-containing film or a carbon-containing film. The etching method further includes (b) forming, under a pressure in the chamber controlled to be 30 mTorr or less, a protective film on a surface of the second film with a plasma generated from a first processing gas including a deposition gas, and (c) etching the first film with a plasma generated from a second processing gas including a hydrogen fluoride gas through the second film on which the protective film is formed.

### CROSS-REFERENCE TO RELATED APPLICATIONS

This application is a continuation of PCT International Application No. PCT/JP2024/045899 filed on Dec. 25, 2024, which claims priority under 35 U.S.C. §119(a) to Japanese Patent Application No. JP 2024-001101, filed on Jan. 9, 2024, all of which are hereby expressly incorporated by reference into the present application.

### BACKGROUND

Exemplary embodiments of the present disclosure relate to an etching method and a plasma processing system.

### SUMMARY

In one exemplary embodiment, an etching method includes (a) providing a substrate into a chamber. The substrate includes a first film and a second film defining an opening on the first film. The first film is a film stack including a first layer containing silicon and oxygen and a second layer containing silicon and nitrogen. The second film includes a metal-containing film or a carbon-containing film. The etching method further includes (b) forming, under a pressure in the chamber controlled to be 30 mTorr or less, a protective film on a surface of the second film with a plasma generated from a first processing gas including a deposition gas, and (c) etching the first film with a plasma generated from a second processing gas including a hydrogen fluoride gas through the second film on which the protective film is formed.

### BRIEF DESCRIPTION OF DRAWINGS

FIG. 1 is a diagram of a plasma processing system, illustrating an example structure;

FIG. 2 is a diagram of a capacitively coupled plasma processing apparatus, illustrating an example structure;

FIG. 3 is a diagram of an example of clogging of openings in a mask;

FIG. 4 is a flowchart of an example of a method MT;

FIG. 5 is a diagram of a substrate W, illustrating an example cross-sectional structure;

FIG. 6 is a diagram of an example of a first protective film PF formed on the surface of a mask MK;

FIG. 7 is a diagram of the substrate W during etching, illustrating an example structure;

FIG. 8A is a flowchart of another example of the method MT;

FIG. 8B is a flowchart of another example of the method MT;

FIG. 8C is a flowchart of another example of the method MT;

FIG. 8D is a flowchart of an example of steps ST12 and ST13 in FIG. 8A;

FIG. 8E is a flowchart of an example of steps ST12 and ST13 in FIG. 8A;

FIG. 9 is a diagram of a substrate W1, illustrating an example cross-sectional structure.

### DETAILED DESCRIPTION

One or more embodiments of the present disclosure will be described below.

One technique for partially etching a silicon-containing film with a plasma in an etching apparatus and then forming a carbon-containing film on the silicon-containing film without plasma generation in a film deposition apparatus is described, for example, in JP 2016-21546. It may be desirable to provide an etching method and a plasma processing system that can reduce clogging of an opening in a mask during etching of a silicon-containing film.

One or more aspects of the present disclosure are directed to a technique for reducing clogging of an opening in a mask.

In one exemplary embodiment, an etching method includes (a) providing a substrate into a chamber. The substrate includes a first film and a second film defining an opening on the first film. The first film is a film stack including a first layer containing silicon and oxygen and a second layer containing silicon and nitrogen. The second film includes a metal-containing film or a carbon-containing film. The etching method further includes (b) forming, under a pressure in the chamber controlled to be 30 mTorr or less, a protective film on a surface of the second film with a plasma generated from a first processing gas including a deposition gas, and (c) etching the first film with a plasma generated from a second processing gas including a hydrogen fluoride gas through the second film on which the protective film is formed.

In one exemplary embodiment, the first film includes a first portion including a plurality of the first layers and a plurality of the second layers alternately stacked on one another and a second portion located on the first portion. The second portion includes a third layer containing silicon and nitrogen. The first layer is thicker than the second layer. The third layer is thicker than the second layer.

In one exemplary embodiment, the second film contains at least one metal selected from the group consisting of tungsten, molybdenum, ruthenium, and titanium.

In one exemplary embodiment, the second film contains the at least one metal and at least one element selected from the group consisting of silicon, carbon, nitrogen, oxygen, boron, hydrogen, and phosphorus.

In one exemplary embodiment, the opening has an opening dimension of 50 nm or less.

In one exemplary embodiment, (b) and (c) are performed simultaneously.

In one exemplary embodiment, a flow rate of the hydrogen fluoride gas included in the second processing gas is higher than a flow rate of the deposition gas included in the first processing gas.

In one exemplary embodiment, a cycle including (b) and (c) is repeated.

In one exemplary embodiment, (a) includes placing the substrate onto a substrate support in the chamber. Steps (b) and (c) include controlling a temperature of the substrate or the substrate support to be 0 °C or lower.

In one exemplary embodiment, the deposition gas includes at least one gas selected from the group consisting of a carbon-containing gas, a silicon-containing gas, and a phosphorus-containing gas.

In one exemplary embodiment, the first processing gas further includes a hydrogen-containing gas other than the deposition gas.

In one exemplary embodiment, the second processing gas further includes a nitrogen-containing gas.

In one exemplary embodiment, the nitrogen-containing gas includes at least one selected from the group consisting of an N2 gas, an NF3 gas, an NH3 gas, an NO gas, and an NO2 gas.

In one exemplary embodiment, (c) includes (c1) a period in which the plasma is generated from the second processing gas further including a nitrogen-containing gas at a first flow rate, and (c2) a period in which the plasma is generated from the second processing gas being free of a nitrogen-containing gas or further including a nitrogen-containing gas at a second flow rate lower than the first flow rate.

In one exemplary embodiment, the second processing gas further includes a phosphorus-containing gas.

In one exemplary embodiment, the second processing gas further includes at least one gas selected from the group consisting of a metal-containing gas, a carbon-free fluorine-containing gas, a gas containing a halogen other than fluorine, an oxygen-containing gas, and a boron-containing gas.

In one exemplary embodiment, (c) includes etching the second layer under a same condition as for the first layer.

In one exemplary embodiment, (c) includes etching the second layer under a condition different from a condition for the first layer.

In one exemplary embodiment, in (c), the second processing gas includes a first etching gas and a second etching gas different from the first etching gas. Step (c) includes (c1) etching the first layer with a plasma generated from the first etching gas, and (c2) etching the second layer with a plasma generated from the second etching gas.

In one exemplary embodiment, an etching method includes (a) providing a substrate into a chamber. The substrate includes a first film and a metal-containing mask on the first film. The first film includes a first layer, a second layer, and a third layer. The first layer includes a first silicon-containing film. The second layer includes a second silicon-containing film different from the first silicon-containing film. The third layer includes a third silicon-containing film different from the first silicon-containing film and the second silicon-containing film. The third layer is located above the first layer and the second layer and has a thickness different from a thickness of the first layer. The metal-containing mask has an opening pattern with an opening dimension of 50 nm or less. The etching method further includes (b) forming, under a pressure in the chamber controlled to be 30 mTorr or less, a protective film on a surface of the metal-containing mask with a plasma generated from a first processing gas including a deposition gas, and (c) etching the first film with a plasma generated from a second processing gas through the metal-containing mask on which the protective film is formed. The second processing gas includes one or more gases to generate hydrogen fluoride in the plasma.

In one exemplary embodiment, the first film includes a film stack including a plurality of the first layers and a plurality of the second layers alternately stacked on one another.

In one exemplary embodiment, the first layer is a silicon oxide film, the second layer is a silicon nitride film, and the third layer is a silicon carbonitride film.

In one exemplary embodiment, a plasma processing system includes a plasma processing apparatus including a chamber, and a controller that performs control operations including (a) providing a substrate into the chamber. The substrate includes a first film and a second film defining an opening on the first film. The first film is a film stack including a first layer containing silicon and oxygen and a second layer containing silicon and nitrogen. The second film includes a metal-containing film or a carbon-containing film. The control operations further include (b) forming, under a pressure in the chamber controlled to be 30 mTorr or less, a protective film on a surface of the second film with a plasma generated from a first processing gas including a deposition gas, and (c) etching the first film with a plasma generated from a second processing gas including a hydrogen fluoride gas through the second film on which the protective film is formed.

One or more embodiments of the present disclosure will be described below with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Structure of Plasma Processing System

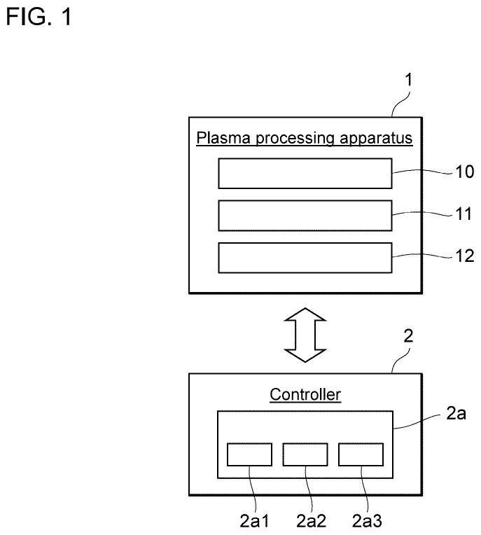

FIG. 1 is a diagram of a plasma processing system, illustrating an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may cause the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading programs from the storage 2a2 and executing the loaded programs. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

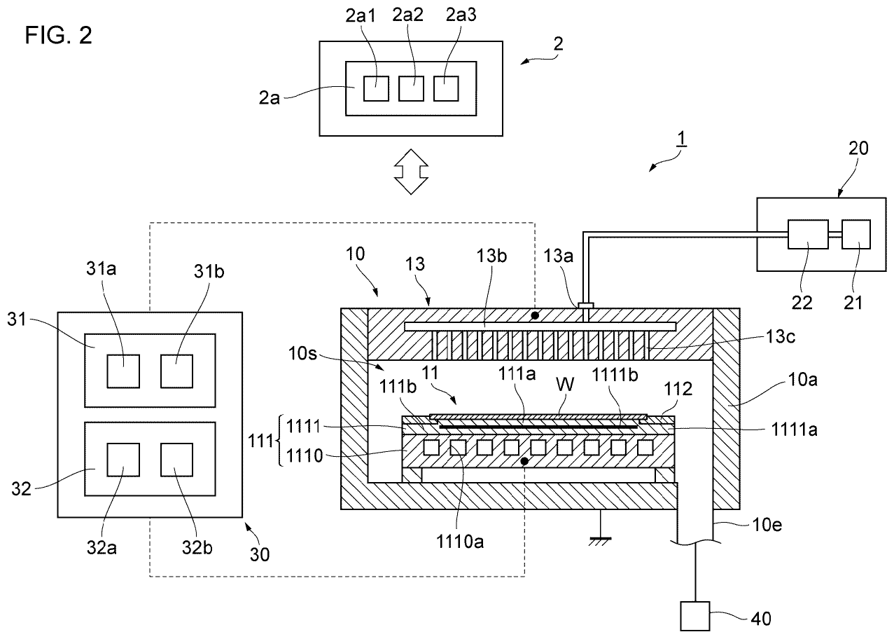

An example structure of a capacitively coupled plasma processing apparatus as an example of the plasma processing apparatus 1 will be described below. FIG. 2 is a diagram of the capacitively coupled plasma processing apparatus, illustrating an example structure.

The capacitively coupled plasma processing apparatus 1 includes the plasma processing chamber 10, the gas supply 20, a power supply 30, and the exhaust system 40. The plasma processing apparatus 1 further includes the substrate support 11 and a gas guide unit (e.g., guide structure). The gas guide unit allows at least one processing gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one processing gas from the gas supply 20 into the plasma processing space 10s. The showerhead 13 includes at least one gas inlet 13a, at least one gas-diffusion compartment 13b, and multiple gas guides 13c. The processing gas supplied to the gas inlet 13a passes through the gas-diffusion compartment 13b and is introduced into the plasma processing space 10s through the multiple gas guides 13c. The showerhead 13 further includes at least one upper electrode. In addition to the showerhead 13, the gas guide structure may include one or more side gas injectors (SGIs) installed in one or more openings in the sidewall 10a.

The gas supply 20 may include at least one gas source 21 and at least one flow controller 22. In one embodiment, the gas supply 20 supplies at least one processing gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates a plasma from at least one processing gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

### Example of Clogging of Openings in Mask

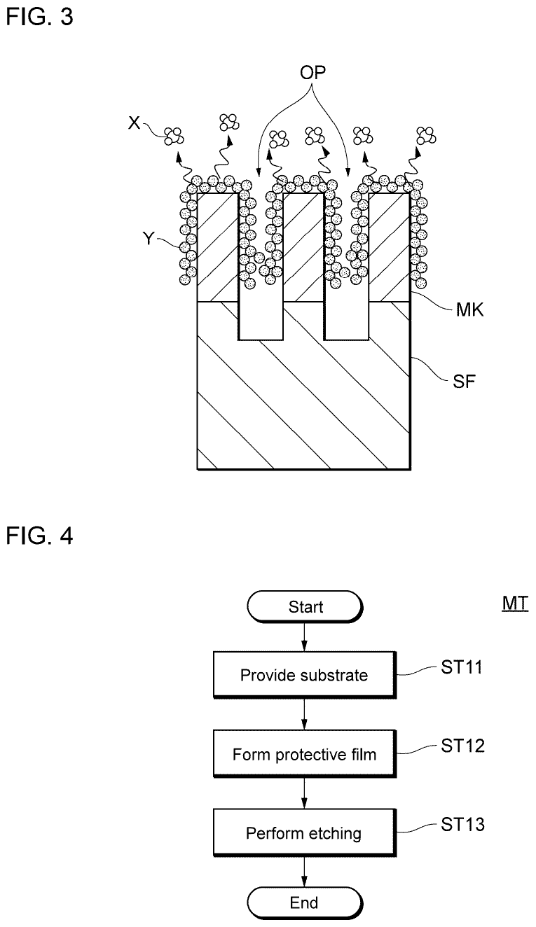

FIG. 3 is a diagram of an example of clogging of openings in a mask. FIG. 3 is a diagram of a silicon-containing film SF etched through a mask MK using a plasma generated from an etching gas including a hydrogen fluoride gas, illustrating an example cross-sectional structure. In one example, the mask MK is a metal-containing mask. Of reaction products derived from the mask MK resulting from etching, as shown in FIG. 3, a product X may volatilize, and a product Y may not volatilize and redeposit on the mask MK. For the mask MK containing tungsten silicide (WSi), for example, the product X may be silicon fluoride, and the product Y may be tungsten or a compound of tungsten. An increased amount of product Y redepositing on the mask MK may cause clogging of openings OP in the mask MK. This prevents an etchant from being fed into the openings OP, stopping etching. Clogging of the openings in the mask MK may occur when, for example, the reaction products have low volatility in a low-temperature environment (0 °C or lower in one example), the etching time increases and reaction products increase, or each opening OP has a smaller opening dimension.

An etching method (hereafter also referred to as a method MT) according to one exemplary embodiment of the present disclosure may reduce clogging of the openings in the mask. The method will be described below with reference to the drawings.

### Example of Method MT

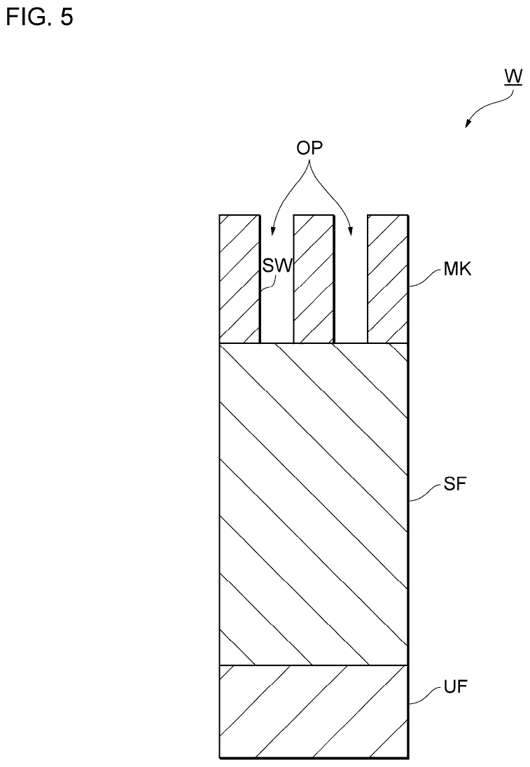

FIG. 4 is a flowchart of an example of the method MT. As shown in FIG. 4, the method MT includes step ST11 of providing a substrate, step ST12 of forming a protective film, and step ST13 of etching. The processing in each step may be performed in the plasma processing system shown in FIG. 1 or FIG. 2. In the example described below, the controller 2 causes the components of the plasma processing apparatus 1 shown in FIG. 2 to implement the method MT on the substrate W.

### Step ST11: Providing Substrate

In step ST11, the substrate W is provided into the plasma processing chamber 10 (hereafter also referred to as the chamber 10). The substrate W is loaded into the chamber 10 with a transfer arm, placed onto the substrate support 11 with a lifter, and clamped on the substrate support 11 as shown in FIG. 2.

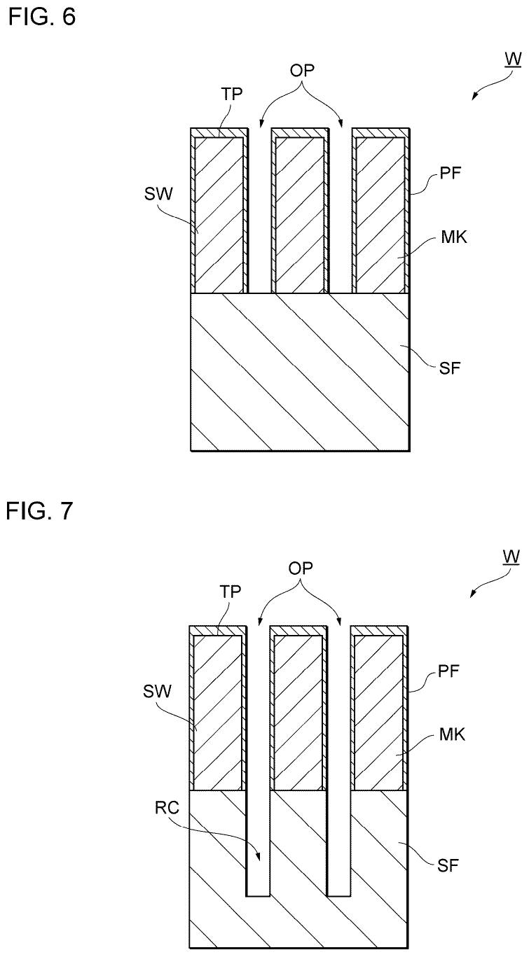

FIG. 5 is a diagram of the substrate W, illustrating an example cross-sectional structure. The substrate W includes the silicon-containing film SF and the mask MK placed on the silicon-containing film SF. The silicon-containing film SF may be located on an underlying film UF. The silicon-containing film SF is an example of a first film in an aspect of the present disclosure. The mask MK is an example of a second film in an aspect of the present disclosure. The substrate W may be used for manufacturing semiconductor devices. Examples of the semiconductor devices include semiconductor memory devices such as a dynamic RAM (DRAM) and a three-dimensional NOT-AND (3D-NAND) flash memory, and a logic device. In one embodiment, the substrate W may be a substrate for a DRAM.

The underlying film UF may be, for example, a silicon wafer or an organic film, a dielectric film, a metal film, or a semiconductor film on the silicon wafer. The underlying film UF may include multiple films stacked on one another.

The silicon-containing film SF is a target film for etching with the method MT. In one exemplary embodiment, the silicon-containing film SF is a film stack including a first layer containing silicon and oxygen and a second layer containing silicon and nitrogen. The first layer may be, for example, a silicon oxide film. The second layer may be, for example, a silicon nitride film. The first layer or the second layer, or both may be doped with an element such as phosphorus, boron, or nitrogen.

In one embodiment, the silicon-containing film SF may include at least two films of a silicon oxide film, a silicon nitride film, a silicon oxynitride film, a polycrystalline silicon film, or a carbon-containing silicon film. These films are stacked on one another. For example, the silicon-containing film SF may include silicon oxide films and silicon nitride films alternately stacked on one another. For example, the silicon-containing film SF may include silicon oxide films and polycrystalline silicon films alternately stacked on one another. For example, the silicon-containing film SF may be a film stack including a silicon nitride film, a silicon oxide film, and a polycrystalline silicon film. For example, the silicon-containing film SF may include a silicon oxide film and a silicon carbonitride film stacked on each other. For example, the silicon-containing film SF may be a film stack including a silicon oxide film, a silicon nitride film, and a silicon carbonitride film. In one embodiment, at least a part of the silicon-containing film SF may be doped with an element such as phosphorus, boron, or nitrogen.

In one embodiment, the mask MK includes a metal-containing film or a carbon-containing film. The mask MK may be a single layer mask including one type of film or a multilayer mask including two or more films.

In one embodiment, the metal-containing film included in the mask MK contains at least one metal (hereafter also referred to as a metal M) selected from the group consisting of tungsten, molybdenum, ruthenium, and titanium. In one embodiment, the metal-containing film contains the metal M and at least one element selected from the group consisting of silicon, carbon, nitrogen, oxygen, boron, hydrogen, and phosphorus. For example, the metal-containing film may be at least one selected from the group consisting of tungsten carbide (WC), tungsten silicide (WSi), tungsten silicon nitride (WSiN), and tungsten silicon carbide (WSiC).

In one embodiment, the carbon-containing film included in the mask MK is an amorphous carbon layer (ACL), a spin-on-carbon (SOC) film, or a photoresist film. The ACL may be doped with an element such as boron and may be, for example, a boron-containing ACL (B-doped ACL), an arsenic-containing ACL (As-doped ACL), a tungsten-containing ACL (W-doped ACL), or a xenon-containing ACL (Xe-doped ACL).

As shown in FIG. 5, the mask MK defines one or more openings OP on the silicon-containing film SF. Each opening OP is a space defined on the silicon-containing film SF and surrounded by a sidewall SW of the mask MK. In other words, the upper surface of the silicon-containing film SF includes a portion covered with the mask MK and portions exposed through the bottoms of the openings OP.

Each opening OP may have any feature in a plan view of the substrate W, or in other words, when the substrate W is viewed from the top to the bottom in FIG. 5. The opening feature may be, for example, a circle, an oval, a rectangle, a line, or a combination of one or more of these features. The mask MK may include multiple sidewalls, which may define multiple openings OP. The mask MK may thus have an opening pattern. For example, the mask MK may have the multiple openings OP that are slits as viewed in plan and arranged at intervals and may thus have a pattern of lines and spaces. For example, the mask MK may have the multiple openings OP that are circular and arranged in dots and may thus have a patterned array. In one embodiment, each opening OP may have an opening dimension of 50 nm or less, 40 nm or less, 30 nm or less, or 20 nm or less.

The underlying film UF, the silicon-containing film SF, and the mask MK may be formed with any method. For example, the underlying film UF, the silicon-containing film SF, and the mask MK may each be formed by chemical vapor deposition (CVD), atomic layer deposition (ALD), physical vapor deposition (PVD), spin coating, or other methods. The mask MK may be formed by, for example, lithography. The openings OP in the mask MK may be formed by etching the mask MK. The underlying film UF, the silicon-containing film SF, and the mask MK may be flat films or uneven films. The substrate W may further include another film under the underlying film UF. In this structure, the silicon-containing film SF and the underlying film UF may have recesses with features corresponding to the openings OP, and these films may be used as a mask for etching the other film.

The process of forming the underlying film UF, the silicon-containing film SF, and the mask MK in the substrate W may be at least partially performed in the chamber 10 as part of step ST11. When the openings OP in the mask MK are formed by etching, for example, the etching in step ST11 and the processing in steps ST12 and ST13 may be performed sequentially in the chamber 10. In one embodiment, all or a part of the substrate W may be formed in an apparatus or a chamber external to the plasma processing apparatus 1 and then provided into the chamber 10.

In one embodiment, after the substrate W is provided onto the central portion 111a of the substrate support 11, the temperature of the substrate support 11 is controlled to be a first temperature by the temperature controller. The first temperature may be, for example, 0 °C or lower, −10 °C or lower, −20 °C or lower, −30 °C or lower, −40 °C or lower, −50 °C or lower, −60 °C or lower, or −70 °C or lower. In one example, controlling the temperature of the substrate support 11 to be the first temperature includes causing the temperature of the heat transfer fluid flowing through the channel 1110a and the temperature of the heater to be the first temperature, or to be a temperature different from the first temperature. The heat transfer fluid may start to flow through the channel 1110a before, after, or at the same time as the substrate W is placed onto the substrate support 11. The temperature of the substrate support 11 may be controlled to be the first temperature before step ST11. In other words, the substrate W may be provided onto the substrate support 11 after the temperature of the substrate support 11 is controlled to be the first temperature.

In one embodiment, the temperature of the substrate W, in place of the substrate support 11, may be controlled to be the first temperature. Controlling the temperature of the substrate W to be the first temperature includes causing at least one of the temperature of the substrate support 11, the temperature of the heat transfer fluid flowing through the channel 1110a, or the temperature of the heater to be the first temperature, or to be a temperature different from the first temperature.

### Step ST12: Forming Protective Film

In step ST12, a protective film (hereafter also referred to as a first protective film) is formed on the surface of the mask MK using a plasma generated from a first processing gas including a deposition gas. Step ST12 includes supplying the first processing gas into the chamber 10 and generating a plasma from the first processing gas.

In one embodiment, the temperature of the substrate support 11 or the substrate W may be controlled to be the first temperature described above or a second temperature different from the first temperature during the processing in step ST12. In one embodiment, the second temperature is 0 °C or lower, −10 °C or lower, −20 °C or lower, −30 °C or lower, −40 °C or lower, −50 °C or lower, −60 °C or lower, or −70 °C or lower.

In one embodiment, the pressure in the chamber 10 may be controlled to be a first pressure during the processing in step ST12. The first pressure may be 30 mTorr or lower, 20 mTorr or lower, or 15 mTorr or lower. The first pressure may be 1 mTorr or higher.

In step ST12, the first processing gas is supplied into the chamber 10. The first processing gas may be supplied into the chamber 10 from, for example, the gas supply 20 through the gas guide 13c in the showerhead 13. In one embodiment, the first processing gas includes a deposition gas. The deposition gas may include at least one gas selected from the group consisting of a carbon-containing gas, a silicon-containing gas, and a phosphorus-containing gas.

The carbon-containing gas may be, for example, a hydrocarbon gas. The hydrocarbon gas may be, for example, at least one selected from the group consisting of a CH4 gas, a C2H2 gas, a C2H4 gas, and a C3H6 gas. The carbon-containing gas may be, for example, a fluorocarbon gas. The fluorocarbon gas may be, for example, at least one selected from the group consisting of a CF4 gas, a C2F2 gas, a C2F4 gas, a C3F6 gas, a C3F8 gas, a C4F6 gas, a C4F8 gas, and a C5F8 gas. The carbon-containing gas may be, for example, a hydrofluorocarbon gas. The hydrofluorocarbon gas may be, for example, at least one selected from the group consisting of a CHF3 gas, a CH2F2 gas, a CH3F gas, a C2HF5 gas, a C2H2F4 gas, a C2H3F3 gas, a C2H4F2 gas, a C3HF7 gas, a C3H2F2 gas, a C3H2F4 gas, a C3H2F6 gas, a C3H3F5 gas, a C4H2F6 gas, a C4H5F5 gas, a C4H2F8 gas, a C5H2F6 gas, a C5H2F10 gas, and a C5H3F7 gas.

The silicon-containing gas may be, for example, at least one selected from the group consisting of an SiF4 gas, an SiCl4 gas, and an SiH4 gas.

The phosphorus-containing gas may be, for example, a phosphorus halide gas. The phosphorus halide gas may be, for example, a phosphorus fluoride gas containing fluorine as a halogen element, such as a PF3 gas or a PF5 gas. The phosphorus halide gas may be, for example, a phosphorus chloride gas containing chlorine as a halogen element, such as a PCl3 gas or a PCl5 gas. The phosphorus halide gas may contain, for example, bromine or iodine as a halogen element, such as a PBr3 gas, a PBr5 gas, or a PI3 gas. The phosphorus halide gas may contain, for example, two or more halogen elements, such as a PClF2 gas, a PCl2F gas, or a PCl2F3 gas. The phosphorus halide gas may be, for example, a phosphorus oxyfluoride gas or a phosphorus oxychloride gas. The phosphorus halide gas may be, for example, a POF3 gas, a POCl3 gas, a POF2Cl2 gas, a POFCl2 gas, or a POF2Cl gas.

In one embodiment, the first processing gas may include a hydrogen-containing gas other than a deposition gas. The hydrogen-containing gas other than the deposition gas may be, for example, an H2 gas or an NH3 gas. The hydrogen-containing gas may facilitate modification of the first protective film formed on the surface of the mask MK and an increase in the film thickness.

In step ST12, a plasma is generated from the first processing gas in the chamber 10. For example, a source RF signal is provided to the lower electrode in the substrate support 11 or the upper electrode in the showerhead 13, or both. An RF electric field is generated between the showerhead 13 and the substrate support 11, generating a plasma from the first processing gas in the chamber 10. This forms the first protective film on the surface of the mask MK. A bias signal may be provided to the lower electrode in the substrate support 11 during plasma generation. In this case, a bias potential is generated between the plasma and the substrate W, thus drawing ions in the plasma toward the substrate W. The bias signal may be a bias DC signal provided from the first DC generator 32a or a bias RF signal provided from the second RF generator 31b. In one embodiment, the bias signal may not be provided to the lower electrode in the substrate support 11.

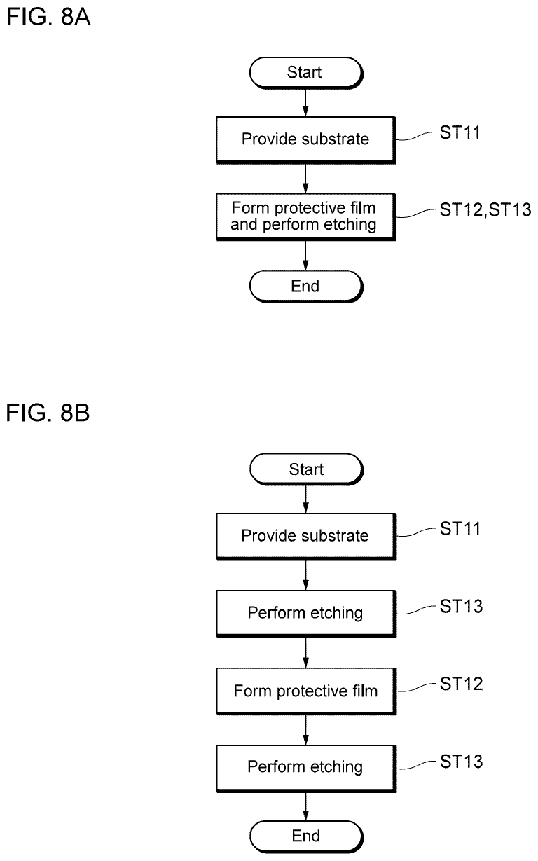

FIG. 6 is a diagram of an example of a first protective film PF formed on the surface of the mask MK. In one embodiment, the first protective film PF may be formed partially or entirely on the surface of the mask MK. For example, the first protective film PF may be formed partially or entirely on the sidewalls SW of the mask MK. For example, the first protective film PF may be formed partially or entirely on an upper surface TP of the mask MK. In the example shown in FIG. 6, the first protective film PF is formed on the sidewalls SW of the mask MK and surrounds the openings OP. The first protective film PF extends over the upper surface TP of the mask MK. In one embodiment, the first protective film PF may not be formed on the bottoms of the openings OP. More specifically, the first protective film PF may be formed on the surface of the mask MK to expose the silicon-containing film SF through the bottoms of the openings OP.

The first protective film PF is a film containing an element derived from the deposition gas (carbon, silicon, or phosphorus in one example) or containing a compound of the element. The first protective film PF protects the mask MK in etching in step ST13.

### Step ST13: Etching

In step ST13, the silicon-containing film SF is etched using a plasma generated from a second processing gas. Step ST13 includes supplying the second processing gas into the chamber 10 and generating a plasma from the second processing gas.

In one embodiment, the temperature of the substrate support 11 or the substrate W may be controlled to be the first temperature or the second temperature described above, or a third temperature different from the first temperature and the second temperature during the processing in step ST13. In one embodiment, the third temperature is 0 °C or lower, −10 °C or lower, −20 °C or lower, −30 °C or lower, −40 °C or lower, −50 °C or lower, −60 °C or lower, or −70 °C or lower.

In one embodiment, the pressure in the chamber 10 may be controlled to be the first pressure described above or a second pressure different from the first pressure during the processing in step ST13. The second pressure may be 30 mTorr or less, 20 mTorr or less, or 15 mTorr or less. The second pressure may be 1 mTorr or higher.

In step ST13, the second processing gas is supplied into the chamber 10. The second processing gas may be supplied into the chamber 10 from, for example, the gas supply 20 through the gas guide 13c in the showerhead 13.

In one embodiment, the second processing gas includes a hydrogen fluoride (HF) gas. The HF gas may have the highest flow rate (partial pressure) among components of the second processing gas excluding an inert component. In one example, the flow rate of the HF gas may be 50 vol % or more, 60 vol % or more, 70 vol % or more, 80 vol % or more, 90 vol % or more, or 95 vol % or more of the total flow rate of all components of the second processing gas (all components of the second processing gas excluding an inert component when the second processing gas includes an inert gas). The flow rate of the HF gas may be less than 100 vol %, 99.5 vol % or less, 98 vol % or less, or 96 vol % or less of the total flow rate of all components of the second processing gas. In one example, the flow rate of the HF gas is 70 to 96 vol % inclusive of the total flow rate of all components of the second processing gas.

In one embodiment, the second processing gas may include, in place of part or all of the HF gas, a gas that can generate an HF species in the plasma. The HF species includes at least any of a gas, radicals, or ions of HF.

The gas that can generate an HF species may be, for example, a hydrofluorocarbon gas. The hydrofluorocarbon gas may have two or more, three or more, or four or more carbon atoms. In one example, the hydrofluorocarbon gas is at least one selected from the group consisting of a CH2F2 gas, a C3H2F4 gas, a C3H2F6 gas, a C3H3F5 gas, a C4H2F6 gas, a C4H5F5 gas, a C4H2F8 gas, a C5H2F6 gas, a C5H2F10 gas, and a C5H3F7 gas. In one example, the hydrofluorocarbon gas is at least one selected from the group consisting of a CH2F2 gas, a C3H2F4 gas, a C3H2F6 gas, and a C4H2F6 gas.

The gas that can generate an HF species may be a mixture gas including, for example, a hydrogen source and a fluorine source. The hydrogen source may be, for example, at least one selected from the group consisting of an H2 gas, an NH3 gas, an H2O gas, an H2O2 gas, and a hydrocarbon gas (e.g., a CH4 gas or a C3H6 gas). The fluorine source may be, for example, a carbon-free fluorine-containing gas, such as an NF3 gas, an SF6 gas, a WF6 gas, or an XeF2 gas. The fluorine source may be a fluorine-containing gas containing carbon, such as a fluorocarbon gas or a hydrofluorocarbon gas. In one example, the fluorocarbon gas may be at least one selected from the group consisting of a CF4 gas, a C2F2 gas, a C2F4 gas, a C3F6 gas, a C3F8 gas, a C4F6 gas, a C4F8 gas, and a C5F8 gas. In one example, the hydrofluorocarbon gas is at least one selected from the group consisting of a CHF3 gas, a CH2F2 gas, a CH3F gas, a C2HF5 gas, and a hydrofluorocarbon gas having three or more carbon atoms (e.g., a C3H2F4 gas, a C3H2F6 gas, or a C4H2F6 gas).

In one embodiment, the second processing gas may include a nitrogen-containing gas. The nitrogen-containing gas may be, for example, an N2 gas, an NF3 gas, an NH3 gas, an NO gas, or an NO2 gas. For the second processing gas including the nitrogen-containing gas, a protective film (hereafter also referred to as a second protective film) may be formed on the sidewalls of the silicon-containing film SF formed by etching. In step ST13, the second protective film may reduce etching of, for example, the silicon-containing film SF in the horizontal direction (hereafter also referred to as bowing).

The nitrogen-containing gas may be a gas free of fluorine atoms, such as an N2 gas, or a gas having F atoms at a relatively low ratio of F atoms to N atoms. In this case, etching of the first protective film formed on the mask MK and the surface of the mask MK is reduced in step ST13, thus further reducing clogging of the openings OP.

The second processing gas may include multiple nitrogen-containing gases. For example, the second processing gas may include a first nitrogen-containing gas and a second nitrogen-containing gas. The first nitrogen-containing gas and the second nitrogen-containing gas may have different ratios of fluorine atoms to nitrogen atoms. In one example, the second nitrogen-containing gas may be free of fluorine atoms or have fluorine atoms at a lower ratio of fluorine atoms to nitrogen atoms than the first nitrogen-containing gas. For example, the first nitrogen-containing gas may be an NF3 gas, and the second nitrogen-containing gas may be an N2 gas. In one embodiment, for the second processing gas including the first nitrogen-containing gas and the second nitrogen-containing gas, the ratio of the first nitrogen-containing gas to the second nitrogen-containing gas may be changed in a continuous or stepwise manner based on, for example, the depth of each recess in the silicon-containing film SF or the processing time (elapsed time from the start of step ST12). In one embodiment, a period in which the second processing gas includes the first nitrogen-containing gas and a period in which the second processing gas includes the second nitrogen-containing gas may be repeated.

In one embodiment, the second processing gas may further include a phosphorus-containing gas. The phosphorus-containing gas may be, for example, a phosphorus halide gas. The phosphorus halide gas may be at least one selected from the group consisting of a PF3 gas, a PF5 gas, a PCl3 gas, a PCl5 gas, a PClF2 gas, a PCl2F gas, and a PCl2F3 gas. In one example, the phosphorus halide gas is a PF3 gas, a PF5 gas, or a PCl3 gas.

In one embodiment, the second processing gas may further include a metal-containing gas. The metal-containing gas contains at least one metal selected from the group consisting of tungsten, titanium, ruthenium, and molybdenum. In one embodiment, the metal-containing gas may further contain halogen. The metal-containing gas may be, for example, a WF2 gas, a WF4 gas, a WF5 gas, a WF6 gas, a WCl2 gas, a WCl4 gas, a WCl5 gas, a WCl6 gas, a MoF4 gas, a MoF6 gas, a MoCl6 gas, or a TiCl4 gas. In one embodiment, the flow rate of the metal-containing gas may be 5 vol % or less of the total flow rate of all components of the second processing gas.

In one embodiment, the second processing gas may further include a gas containing a halogen other than fluorine. The gas containing a halogen other than fluorine is, for example, at least one of a chlorine-containing gas, a bromine-containing gas, or an iodine-containing gas. In one example, the chlorine-containing gas is at least one gas selected from the group consisting of Cl2, SiCl2, SiCl4, CCl4, SiH2Cl2, Si2Cl6, CHCl3, SO2Cl2, BCl3, PCl3, PCl5, and POCl3. In one example, the bromine-containing gas is at least one gas selected from the group consisting of Br2, HBr, CBr2F2, C2F5Br, PBr3, PBr5, POBr3, and BBr3. In one example, the iodine-containing gas is at least one gas selected from the group consisting of HI, CF3I, C2F5I, C3F7I, IF5, IF7, I2, and PI3. In one example, the gas containing a halogen other than fluorine may be at least one selected from the group consisting of a Cl2 gas, a Br2 gas, and an HBr gas. In one example, the gas containing a halogen other than fluorine is a Cl2 gas or an HBr gas.

In one embodiment, the second processing gas may further include an oxygen-containing gas. The oxygen-containing gas may be, for example, at least one gas selected from the group consisting of O2, CO, CO2, H2O , and H2O2. In one example, the oxygen-containing gas may be a gas other than H2O, or specifically, at least one gas selected from the group consisting of O2, CO, CO2, and H2O2. The flow rate of the oxygen-containing gas may be adjusted based on the flow rate of another gas (e.g., a carbon-containing gas) included in the second processing gas.

In one embodiment, the second processing gas may further include a carbon-free fluorine-containing gas, such as an NF3 gas, an SF6 gas, a WF6 gas, or an XeF2 gas.

In one embodiment, the second processing gas may further include a boron-containing gas. The boron-containing gas may be, for example, at least one selected from the group consisting of a BCl3 gas, a BBr3 gas, a BF3 gas, and a B2H6 gas.

In one embodiment, the second processing gas may further include an inert gas. In one example, the inert gas may be a noble gas such as an Ar gas, a He gas, and a Kr gas, or an N2 gas.

In step ST13, a plasma is generated from the second processing gas in the chamber 10. For example, a source RF signal is provided to the lower electrode in the substrate support 11 or the upper electrode in the showerhead 13, or both. An RF electric field is generated between the showerhead 13 and the substrate support 11, generating a plasma from the etching gas in the chamber 10. The silicon-containing film SF exposed through the openings OP in the mask MK is etched with active species such as ions and radicals in the plasma. A bias signal may be provided to the lower electrode in the substrate support 11 during plasma generation. In this case, a bias potential is generated between the plasma and the substrate W, thus drawing ions in the plasma toward the substrate W. This may facilitate etching. The bias signal may be a bias DC signal provided from the first DC generator 32a or a bias RF signal provided from the second RF generator 31b. In one embodiment, the bias signal may not be provided to the lower electrode in the substrate support 11.

In one embodiment, the first layer containing silicon and oxygen and the second layer containing silicon and nitrogen in the silicon-containing film SF may be etched under the same etching condition or different etching conditions. The etching condition includes any one or more of the temperature of the substrate support 11 or the substrate W, the pressure in the chamber 10, the power of the source RF signal or the bias signal, and the flow rate or the type of the second processing gas.

For example, the second processing gas may be a first etching gas and a second etching gas different from the first etching gas. In this case, the first layer is etched with a plasma generated from the first etching gas, and the second layer is etched with a plasma generated from the second etching gas. The first etching gas or the second etching gas, or both may include a hydrogen fluoride gas. When both the first etching gas and the second etching gas include a hydrogen fluoride gas, the flow rate ratio of the hydrogen fluoride in the first etching gas may be different from that in the second etching gas. When both the first etching gas and the second etching gas include a hydrogen fluoride gas, a gas other than the hydrogen fluoride gas included in the first etching gas may be different from that in the second etching gas.

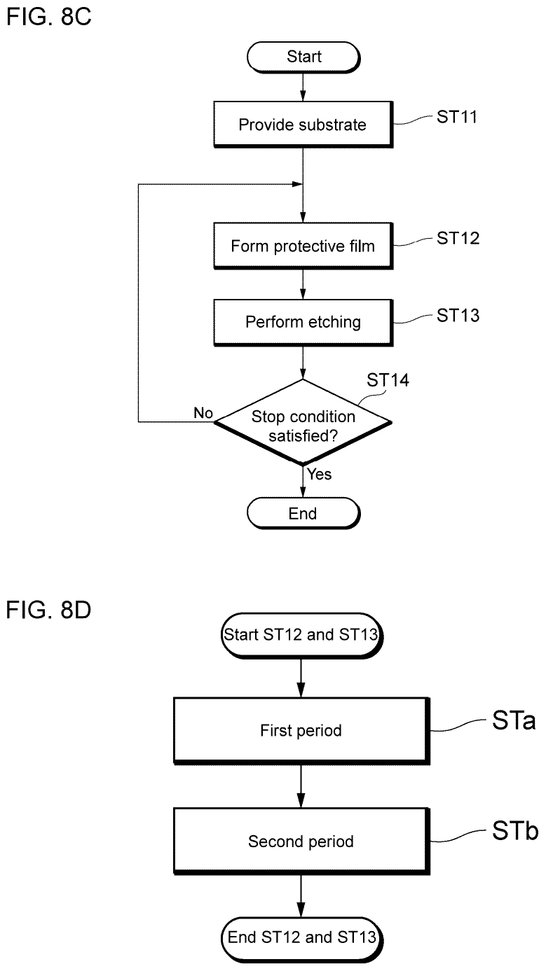

FIG. 7 is a diagram of the substrate W during etching, illustrating an example structure. As shown in FIG. 7, portions of the silicon-containing film SF exposed through the openings OP are etched in the depth direction (from the top to the bottom in FIG. 7) with the active species in the plasma. This forms recesses RC with features corresponding to the openings OP.

In etching in step ST13, the protective film PF protects the surface of the mask MK (the sidewalls SW or the upper surface TP, or both) on which the protective film PF is formed. In other words, the protective film PF reduces etching of the surface of the mask MK with the active species in the plasma. This reduces etching of the mask MK, thus reducing the reaction products derived from the mask MK and reducing redeposition of the reaction products on the mask MK. This may reduce clogging of the openings in the mask MK. This reduces etching of the mask MK, thus improving the etching selectivity of the silicon-containing film SF over the mask MK in etching.

The etching in step ST13 is stopped when a given stop condition is satisfied. The stop condition may be set as appropriate based on, for example, the etching time or the depth of each recess RC.

### Modifications

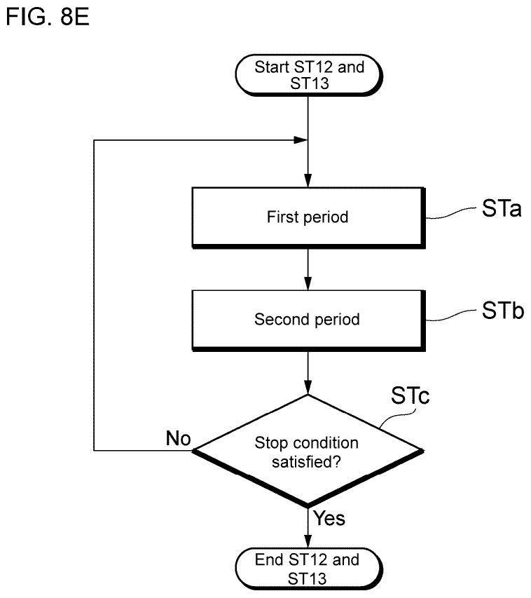

FIGS. 8A to 8C are each a flowchart of another example of the method MT. As shown in FIG. 8A, steps ST12 and ST13 may be performed simultaneously in the method MT. More specifically, the processing gas including the first processing gas and the second processing gas may be simultaneously supplied into the chamber 10 to generate a plasma from the processing gas. In this case, formation of the protective film PF and etching of the silicon-containing film SF proceed in parallel. In this case, the flow rate of the HF gas included in the processing gas may be higher than the flow rate of the deposition gas (e.g., a carbon-containing gas, a phosphorus-containing gas, or a silicon-containing gas). For the first processing gas including a hydrogen-containing gas other than the deposition gas described above, the flow rate of the hydrogen-containing gas included in the processing gas may be substantially the same as the flow rate of the HF gas. For example, the ratio of the flow rate of the hydrogen-containing gas to the flow rate of the HF gas may be 0.4 to 1.5 inclusive, 0.5 to 1.4 inclusive, or 0.8 to 1.2 inclusive. In one example, the flow rate of the hydrogen-containing gas included in the processing gas is substantially the same as the flow rate of the HF gas.

In the method MT, steps ST12 and ST13 may be performed in any order and any number of times that are set as appropriate. For example, the silicon-containing film SF may be etched first by a certain degree (step ST13), then the protective film may be formed on the surface of the mask MK (step ST12), and the silicon-containing film SF may be etched again (step ST13), as shown in FIG. 8B. For example, steps ST12 and ST13 as one cycle may be repeated multiple times until the stop condition is satisfied (Yes in step ST14), as shown in FIG. 8C. In other words, the formation of the protective film PF on the surface of the mask MK and the etching of the silicon-containing film SF may be repeated alternately. As in the examples in FIGS. 8A to 8C, the protective film PF may be formed as described below when step ST12 is performed with the recesses RC formed on the silicon-containing film SF. For example, the protective film PF may be formed partially or entirely on the sidewalls of the silicon-containing film SF surrounding the recesses RC, in addition to the surface of the mask MK. For example, the protective film PF may be formed on the surface of the mask MK alone and may not be formed on the sidewalls of the silicon-containing film SF surrounding the recesses RC.

FIG. 8D is a flowchart of an example of steps ST12 and ST13 in FIG. 8A. As described above, steps ST12 and ST13 are performed simultaneously in the method MT in this example. More specifically, the first processing gas and the second processing gas are simultaneously supplied into the chamber 10 to generate a plasma from the processing gas. In this case, the second processing gas may be supplied into the chamber 10 in a first period (step STa) in which the second processing gas includes a nitrogen-containing gas at a first flow rate and a second period (step STb) in which the second processing gas is free of a nitrogen-containing gas or includes a nitrogen-containing gas at a second flow rate lower than the first flow rate. As shown in FIG. 8E, the first period and the second period as one cycle may be repeated multiple times until the stop condition is satisfied (Yes in step STc).

The second processing gas including a nitrogen-containing gas may allow the first protective film to be formed on the sidewalls of the mask MK and the second protective film to be formed on the sidewalls of the silicon-containing film SF formed by etching. In this case, the second protective film may also be formed on the bottom surface of the silicon-containing film SF under a certain etching condition. The second protective film may lower the etching rate of the silicon-containing film SF. In this example, however, the first processing gas is free of a nitrogen-containing gas or includes a nitrogen-containing gas at a lower flow rate than in step STa in the second period. This reduces formation of the second protective film in the period. Thus, the etching rate of the silicon-containing film SF is less likely to be lowered by the second protective film.

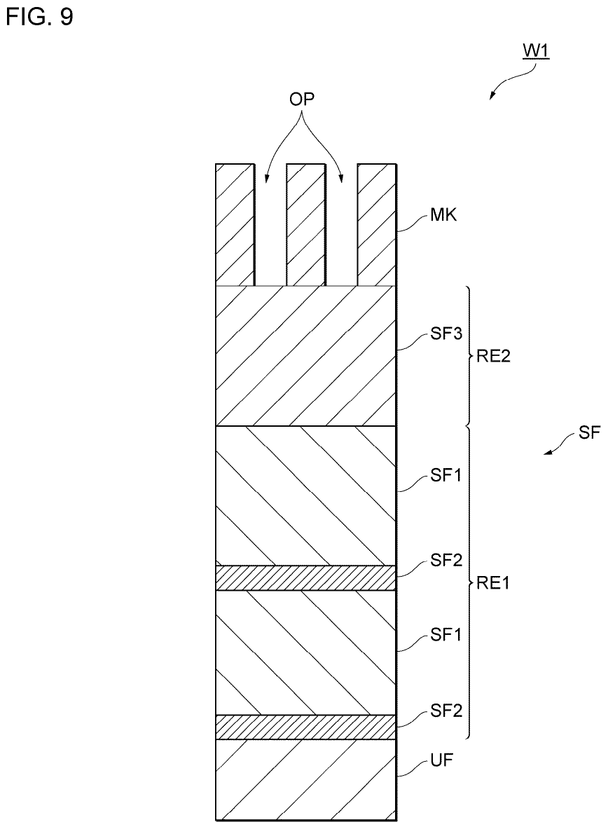

FIG. 9 is a diagram of another example of the substrate W (hereafter referred to as a substrate W1). As shown in FIG. 9, the silicon-containing film SF in the substrate W1 includes a first portion RE1 and a second portion RE2 on the first portion RE1. The first portion RE1 is a film stack including first layers SF1 and second layers SF2 alternately stacked on one another. The second portion RE2 is a film including a third layer SF3. The first layer SF1 is a film containing silicon and oxygen and is, for example, a silicon oxide film. The second layer SF2 is a film containing silicon and nitrogen and is, for example, a silicon nitride film. The third layer SF3 may be a silicon-containing film different from the first layer SF1. The third layer SF3 may be a silicon-containing film that is the same as or different from the second layer SF2. The third layer SF3 may be a film containing silicon and nitrogen and is, for example, a silicon nitride film or a silicon carbonitride film. The first layer SF1 may be thicker than the second layer SF2. The third layer SF3 may be thicker than the second layer SF2.

### EXAMPLES

One or more embodiments of the present disclosure are not limited to the examples and the reference examples described below.

### Example 1

In Example 1, a substrate with the same structure as the substrate W1 shown in FIG. 9 was etched using the plasma processing apparatus 1 described with reference to FIG. 2 and the procedure described with reference to FIG. 8A. The mask MK was a WSiN film with a hole pattern with an opening dimension of 20 nm. The processing gas including a CH₄ gas as the first processing gas and an HF gas as the second processing gas was used. The flow rate of the CH₄ gas was 60% of the flow rate of the HF gas. The pressure of the chamber 10 was set to 30 mTorr or less. The etching was performed for 450 seconds.

### Example 2

In Example 2, the processing gas including a CH₄ gas as the first processing gas and an HF gas as the second processing gas was used. The flow rate of the CH₄ gas was 40% of the flow rate of the HF gas. The other conditions were the same as in Example 1.

### Example 3

In Example 3, the processing gas including a CH₄ gas and an H₂ gas as the first processing gas and an HF gas as the second processing gas was used. The flow rate of the CH₄ gas was 40% of the flow rate of the HF gas. The flow rate of the H₂ gas was the same as the flow rate of the HF gas. The other conditions were the same as in Example 1.

### Example 4

In Example 4, the processing gas including a CH₄ gas and an H₂ gas as the first processing gas and an HF gas as the second processing gas was used. The flow rate of the CH₄ gas was 20% of the flow rate of the HF gas. The flow rate of the H₂ gas was twice the flow rate of the HF gas. The other conditions were the same as in Example 1.

In each of Examples 1 to 4, the etching reached the underlying film UF, and no etching stop occurred. In other words, clogging of the openings in the mask MK was reduced in each of Examples 1 to 4. In Examples 1, 3, and 4, almost no deposit derived from the mask MK was observed on the sidewalls of the mask MK at the end of etching. In Example 2, a deposit derived from the mask MK was observed on a part of the sidewalls of the mask MK. The results in Examples 1 to 4 show that the deposit derived from the mask MK increases as the flow rate ratio of the CH₄ gas to the HF gas is smaller, but the increase in the deposit may be reduced by adding an H₂ gas to the deposition gas.

### Example 5

In Example 5, the processing gas including a CH₄ gas and an H₂ gas as the first processing gas and an HF gas and an NF₃ gas as the second processing gas was used. The flow rate of the CH₄ gas was 40% of the flow rate of the HF gas. The flow rate of the H₂ gas was the same as the flow rate of the HF gas. The other conditions were the same as in Example 1.

### Example 6

In Example 6, the processing gas including a CH₄ gas and an H₂ gas as the first processing gas and an HF gas and an NF₃ gas as the second processing gas was used. The flow rate of the CH₄ gas was 40% of the flow rate of the HF gas. The flow rate of the H₂ gas was the same as the flow rate of the HF gas. In Example 6, steps ST12 and ST13 including the first period and the second period were performed as shown in FIGS. 8D and 8E. In the first period, the second processing gas including the NF₃ gas was used. In the second period, the second processing gas that is free of the NF₃ gas was used. The other conditions were the same as in Example 1.

In each of Examples 5 and 6 as well, the etching reached the underlying film UF, and no etching stop occurred. In other words, clogging of the openings in the mask MK was reduced in Examples 5 and 6 as well. In Examples 5 and 6, bowing of the silicon-containing film SF was also reduced compared with the structures in Examples 1 to 4. In these Examples, the second protective film was observed on the silicon-containing film SF. The second protective film contained ammonium fluorosilicate. The silicon-containing film SF was less likely to have a lower etching rate in Example 6 than in Example 5. The second protective film seems to be less likely to form on the bottom surface of the silicon-containing film SF in the second period.

The embodiments of the present disclosure further include the aspects described below.
Aspect 1

An etching method, comprising:
(a) providing a substrate into a chamber, the substrate including a first film and a second film defining an opening on the first film, the first film being a film stack including a first layer comprising silicon and oxygen and a second layer comprising silicon and nitrogen, the second film including a metal-containing film or a carbon-containing film;
(b) forming, under a pressure in the chamber controlled to be 30 mTorr or less, a protective film on a surface of the second film with a plasma generated from a first processing gas including a deposition gas; and
(c) etching the first film with a plasma generated from a second processing gas including a hydrogen fluoride gas through the second film on which the protective film is formed.
Aspect 2

The etching method according to Aspect 1, wherein
the first film includes a first portion including a plurality of the first layers and a plurality of the second layers alternately stacked on one another and a second portion located on the first portion, and the second portion includes a third layer comprising silicon and nitrogen, and
the first layer is thicker than the second layer, and the third layer is thicker than the second layer.
Aspect 3

The etching method according to Aspect 1 or Aspect 2, wherein
the second film comprises at least one metal selected from the group consisting of tungsten, molybdenum, ruthenium, and titanium.
Aspect 4

The etching method according to Aspect 3, wherein
the second film comprises the at least one metal and at least one element selected from the group consisting of silicon, carbon, nitrogen, oxygen, boron, hydrogen, and phosphorus.
Aspect 5

The etching method according to any one of Aspects 1 to 4, wherein
the opening has an opening dimension of 50 nm or less.
Aspect 6

The etching method according to any one of Aspects 1 to 5, wherein
(b) and (c) are performed simultaneously.
Aspect 7

The etching method according to any one of Aspects 1 to 6, wherein
a flow rate of the hydrogen fluoride gas included in the second processing gas is higher than a flow rate of the deposition gas included in the first processing gas.
Aspect 8

The etching method according to any one of Aspects 1 to 7, wherein
a cycle including (b) and (c) is repeated.
Aspect 9

The etching method according to any one of Aspects 1 to 8, wherein
(a) includes placing the substrate onto a substrate support in the chamber, and
(b) and (c) include controlling a temperature of the substrate or the substrate support to be 0 °C or lower.
Aspect 10

The etching method according to any one of Aspects 1 to 9, wherein
the deposition gas includes at least one gas selected from the group consisting of a carbon-containing gas, a silicon-containing gas, and a phosphorus-containing gas.
Aspect 11

The etching method according to Aspect 10, wherein
the first processing gas further includes a hydrogen-containing gas other than the deposition gas.
Aspect 12

The etching method according to any one of Aspects 1 to 11, wherein
the second processing gas further includes a nitrogen-containing gas.
Aspect 13

The etching method according to Aspect 12, wherein
the nitrogen-containing gas includes at least one selected from the group consisting of an N₂ gas, an NF₃ gas, an NH₃ gas, an NO gas, and an NO₂ gas.
Aspect 14

The etching method according to Aspect 6, wherein
(c) includes
   (c1) a period in which the plasma is generated from the second processing gas further including a nitrogen-containing gas at a first flow rate, and
   (c2) a period in which the plasma is generated from the second processing gas being free of a nitrogen-containing gas or further including a nitrogen-containing gas at a second flow rate lower than the first flow rate.
Aspect 15

The etching method according to any one of Aspects 1 to 14, wherein
the second processing gas further includes a phosphorus-containing gas.
Aspect 16

The etching method according to any one of Aspects 1 to 15, wherein
the second processing gas further includes at least one gas selected from the group consisting of a metal-containing gas, a carbon-free fluorine-containing gas, a gas containing a halogen other than fluorine, an oxygen-containing gas, and a boron-containing gas.
Aspect 17

The etching method according to any one of Aspects 1 to 16, wherein
(c) includes etching the second layer under a same condition as for the first layer.
Aspect 18

The etching method according to any one of Aspects 1 to 16, wherein
(c) includes etching the second layer under a condition different from a condition for the first layer.
Aspect 19

The etching method according to Aspect 18, wherein
in (c), the second processing gas includes a first etching gas and a second etching gas different from the first etching gas, and
(c) includes
   (c1) etching the first layer with a plasma generated from the first etching gas, and
   (c2) etching the second layer with a plasma generated from the second etching gas.
Aspect 20

An etching method, comprising:
(a) providing a substrate into a chamber, the substrate including a first film and a metal-containing mask on the first film, the first film including a first layer, a second layer, and a third layer, the first layer including a first silicon-containing film, the second layer including a second silicon-containing film different from the first silicon-containing film, the third layer including a third silicon-containing film different from the first silicon-containing film and the second silicon-containing film, the third layer being located above the first layer and the second layer and having a thickness different from a thickness of the first layer, the metal-containing mask having an opening pattern with an opening dimension of 50 nm or less;
(b) forming, under a pressure in the chamber controlled to be 30 mTorr or less, a protective film on a surface of the metal-containing mask with a plasma generated from a first processing gas including a deposition gas; and
(c) etching the first film with a plasma generated from a second processing gas through the metal-containing mask on which the protective film is formed, the second processing gas including one or more gases to generate hydrogen fluoride in the plasma.
Aspect 21

The etching method according to Aspect 20, wherein
the first film includes a film stack including a plurality of the first layers and a plurality of the second layers alternately stacked on one another.
Aspect 22

The etching method according to Aspect 20 or Aspect 21, wherein
the first layer is a silicon oxide film, the second layer is a silicon nitride film, and the third layer is a silicon carbonitride film.
Aspect 23

A plasma processing system, comprising:
a plasma processing apparatus including a chamber; and
a controller configured to perform control operations including
   (a) providing a substrate into the chamber, the substrate including a first film and a second film defining an opening on the first film, the first film being a film stack including a first layer comprising silicon and oxygen and a second layer comprising silicon and nitrogen, the second film including a metal-containing film or a carbon-containing film,
   (b) forming, under a pressure in the chamber controlled to be 30 mTorr or less, a protective film on a surface of the second film with a plasma generated from a first processing gas including a deposition gas, and
   (c) etching the first film with a plasma generated from a second processing gas including a hydrogen fluoride gas through the second film on which the protective film is formed.
Aspect 24

A program executable by a computer included in a plasma processing system including a plasma processing apparatus and a controller, the plasma processing apparatus including a chamber, the program causing the computer to perform control operations comprising:
(a) providing a substrate into the chamber, the substrate including a first film and a second film defining an opening on the first film, the first film being a film stack including a first layer comprising silicon and oxygen and a second layer comprising silicon and nitrogen, the second film including a metal-containing film or a carbon-containing film;
(b) forming, under a pressure in the chamber controlled to be 30 mTorr or less, a protective film on a surface of the second film with a plasma generated from a first processing gas including a deposition gas; and
(c) etching the first film with a plasma generated from a second processing gas including a hydrogen fluoride gas through the second film on which the protective film is formed.
Aspect 25

A storage medium storing the program according to Aspect 24.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

1. An etching method, comprising:
(a) providing a substrate into a chamber, the substrate including a first film and a second film defining an opening on the first film, the first film being a film stack including a first layer comprising silicon and oxygen and a second layer comprising silicon and nitrogen, the second film including a metal-containing film or a carbon-containing film;
(b) forming, under a pressure in the chamber controlled to be 30 mTorr or less, a protective film on a surface of the second film with a plasma generated from a first processing gas including a deposition gas; and
(c) etching the first film with a plasma generated from a second processing gas including a hydrogen fluoride gas through the second film on which the protective film is formed.

2. The etching method according to claim 1, wherein
the first film includes a first portion including a plurality of the first layer and a plurality of the second layer alternately stacked on one another and a second portion located on the first portion, and the second portion includes a third layer comprising silicon and nitrogen, and
the first layer is thicker than the second layer, and the third layer is thicker than the second layer.

3. The etching method according to claim 1, wherein
the second film comprises at least one metal selected from the group consisting of tungsten, molybdenum, ruthenium, and titanium.

4. The etching method according to claim 3, wherein
the second film comprises the at least one metal and at least one element selected from the group consisting of silicon, carbon, nitrogen, oxygen, boron, hydrogen, and phosphorus.

5. The etching method according to claim 1, wherein
the opening has an opening dimension of 50 nm or less.

6. The etching method according to claim 1, wherein
(b) and (c) are performed simultaneously.

7. The etching method according to claim 6, wherein
a flow rate of the hydrogen fluoride gas included in the second processing gas is higher than a flow rate of the deposition gas included in the first processing gas.

8. The etching method according to claim 1, wherein
a cycle including (b) and (c) is repeated.

9. The etching method according to claim 1, wherein
(a) includes placing the substrate onto a substrate support in the chamber, and
(b) and (c) include controlling a temperature of the substrate or the substrate support to be 0 °C or lower.

10. The etching method according to claim 1, wherein
the deposition gas includes at least one gas selected from the group consisting of a carbon-containing gas, a silicon-containing gas, and a phosphorus-containing gas.

11. The etching method according to claim 1, wherein
the first processing gas further includes a hydrogen-containing gas other than the deposition gas.

12. The etching method according to claim 1, wherein
the second processing gas further includes a nitrogen-containing gas.

13. The etching method according to claim 12, wherein
the nitrogen-containing gas includes at least one selected from the group consisting of an N₂ gas, an NF₃ gas, an NH₃ gas, an NO gas, and an NO₂ gas.

14. The etching method according to claim 6, wherein
(c) includes
(c1) a period in which the plasma is generated from the second processing gas further including a nitrogen-containing gas at a first flow rate, and
(c2) a period in which the plasma is generated from the second processing gas being free of a nitrogen-containing gas or further including a nitrogen-containing gas at a second flow rate lower than the first flow rate.

15. The etching method according to claim 1, wherein
the second processing gas further includes a phosphorus-containing gas.

16. The etching method according to claim 1, wherein
the second processing gas further includes at least one gas selected from the group consisting of a metal-containing gas, a carbon-free fluorine-containing gas, a gas containing a halogen other than fluorine, an oxygen-containing gas, and a boron-containing gas.

17. The etching method according to claim 1, wherein
(c) includes etching the second layer under the same etching condition as the etching of the first layer.

18. The etching method according to claim 1, wherein
(c) includes etching the second layer under an etching condition different from an etching condition for the first layer.

19. The etching method according to claim 18, wherein
in (c), the second processing gas includes a first etching gas and a second etching gas different from the first etching gas, and
at least one of the first etching gas or the second etching gas includes the hydrogen fluoride gas, and
(c) includes
(c1) etching the first layer with a plasma generated from the first etching gas, and
(c2) etching the second layer with a plasma generated from the second etching gas.

20. An etching method, comprising:
(a) providing a substrate into a chamber, the substrate including a first film and a metal-containing mask on the first film, the first film including a first layer, a second layer, and a third layer, the first layer including a first silicon-containing film, the second layer including a second silicon-containing film different from the first silicon-containing film, the third layer including a third silicon-containing film different from the first silicon-containing film and the second silicon-containing film, the third layer being located above the first layer and the second layer and having a thickness different from a thickness of the first layer, the metal-containing mask having an opening pattern with an opening dimension of 50 nm or less;
(b) forming, under a pressure in the chamber controlled to be 30 mTorr or less, a protective film on a surface of the metal-containing mask with a plasma generated from a first processing gas including a deposition gas; and
(c) etching the first film with a plasma generated from a second processing gas through the metal-containing mask on which the protective film is formed, the second processing gas including one or more gases to generate hydrogen fluoride in the plasma.

21. The etching method according to claim 20, wherein
the first film includes a film stack including a plurality of the first layer and a plurality of the second layer alternately stacked on one another.

22. The etching method according to claim 20, wherein
the first layer is a silicon oxide film, the second layer is a silicon nitride film, and the third layer is a silicon carbonitride film.

23. A plasma processing system, comprising:
a plasma processing apparatus including a chamber; and
controller circuitry configured to control the plasma processing apparatus to perform operations including:
(a) receiving a substrate into the chamber, the substrate including a first film and a second film defining an opening on the first film, the first film being a film stack including a first layer comprising silicon and oxygen and a second layer comprising silicon and nitrogen, the second film including a metal-containing film or a carbon-containing film,
(b) forming, under a pressure in the chamber controlled to be 30 mTorr or less, a protective film on a surface of the second film with a plasma generated from a first processing gas including a deposition gas, and
(c) etching the first film with a plasma generated from a second processing gas including a hydrogen fluoride gas through the second film on which the protective film is formed.
